(19) United States
(12) Patent Application Publication
(10) Pub. No.: US 2025/0294999 A1
(43) Pub. Date: Sep. 18, 2025

(54) DISPLAY PANELS, MANUFACTURING METHOD OF DISPLAY PANELS, AND DISPLAY DEVICES

(71) Applicant: Shenzhen China Star Optoelectronics Semiconductor Display Technology Co., Ltd., Shenzhen (CN)

(72) Inventor: Ri HONG, Shenzhen (CN)

(73) Assignee: Shenzhen China Star Optoelectronics Semiconductor Display Technology Co., Ltd., Shenzhen (CN)

(21) Appl. No.: 19/077,244

(22) Filed: Mar. 12, 2025

(30) Foreign Application Priority Data
Mar. 12, 2024 (CN) 202410283143.1

(51) Int. Cl. H10K 59/80; H10K 59/12; H10K 59/122; H10K 59/131

(52) U.S. Cl. CPC H10K 59/80523; H10K 59/1201; H10K 59/122; H10K 59/1315

(57) ABSTRACT

A display panel, a manufacturing method of a display panel, and a display device are provided. The display panel includes a substrate, a pixel defining layer, a light-emitting layer, a first cathode layer and a second cathode layer. The pixel defining layer is disposed on the substrate, the pixel defining layer includes a first spacer layer and a conductive layer that are stacked. A plurality of pixel openings penetrating the first spacer layer and the conductive layer are disposed in the pixel defining layer. The first cathode layer includes a plurality of cathode portions disposed in the plurality of pixel openings, and the plurality of cathode portions are electrically connected to the conductive layer. The second cathode layer is disposed on a side of the pixel defining layer away from the substrate; and the second cathode layer is electrically connected to the conductive layer.

### CROSS-REFERENCE TO RELATED APPLICATION

This application claims priority to and the benefit of Chinese Patent Application No. 202410283143.1, filed on Mar. 12, 2024, the disclosure of which is incorporated herein by reference in its entirety.

### TECHNICAL FIELD

The present disclosure relates to the field of display technology, and in particular, to display panels, manufacturing methods of display panels, and display devices.

### BACKGROUND

Organic light-emitting diode (OLED) display panels have received widespread attention due to its display characteristics and qualities that surpass those of liquid crystal display (LCD), such as being lighter and thinner, short response time, low driving voltage, better display colors and display viewing angles. Organic light-emitting diode display panel has been developing rapidly in recent years, it can not only be used in the curved display, but also gradually develop into medium and large sizes.

However, in OLED display panels with medium and large sizes, since it is necessary to dispose the cathode layer on the entire surface, and signal transmission is also required to be transmitted on the entire surface, voltage drop easily occurs, resulting in non-uniform display of the display panel.

### SUMMARY

Embodiments of the present disclosure provide a display panel, a manufacturing method of a display panel, and a display device, which can address the voltage drop phenomenon of the display panel.

An embodiment of the present disclosure provides a display panel including: a substrate; a pixel defining layer disposed on the substrate, wherein the pixel defining layer includes a first spacer layer and a conductive layer that are stacked, the first spacer layer is located between the conductive layer and the substrate, and a plurality of pixel openings penetrating the first spacer layer and the conductive layer are disposed in the pixel defining layer; a light-emitting layer including a plurality of light-emitting portions disposed in the plurality of pixel openings; a first cathode layer including a plurality of cathode portions disposed in the plurality of pixel openings, each of the plurality of cathode portions is located on a side of each of the plurality of light-emitting portions away from the substrate, and the plurality of cathode portions are electrically connected to the conductive layer; and a second cathode layer disposed on a side of the pixel defining layer away from the substrate; wherein the second cathode layer is electrically connected to the conductive layer.

According to the above object of the present disclosure, an embodiment of the present disclosure further provides a manufacturing method of a display panel including: forming a pixel defining layer on a substrate, wherein the pixel defining layer comprises a first spacer layer and a conductive layer that are stacked, the first spacer layer is located between the conductive layer and the substrate, and a plurality of pixel openings penetrating the first spacer layer and the conductive layer are disposed in the pixel defining layer; forming a light-emitting layer and a first cathode layer on the pixel defining layer, wherein the light-emitting layer comprises a plurality of light-emitting portions formed in the plurality of pixel openings, the first cathode layer comprises a plurality of cathode portions formed in the plurality of pixel openings, each of the plurality of cathode portions is formed on a side of each of the plurality of light-emitting portions away from the substrate, and the plurality of cathode portions are electrically connected to the conductive layer; and forming a second cathode layer on a side of the pixel defining layer away from the substrate, and the second cathode layer is electrically connected to the conductive layer.

According to the above object of the present disclosure, an embodiment of the present disclosure further provides a display device, the display device includes the display panel described above.

### BRIEF DESCRIPTION OF THE DRAWINGS

The technical solutions and other beneficial effects of the present disclosure will become apparent through a detailed description of specific embodiments of the present disclosure below in combination with the accompanying drawings.

FIG. 1 is a schematic diagram of a structure of a display panel according to some embodiments of the present disclosure;

FIG. 2 is a schematic diagram of a top view structure of a conductive layer according to some embodiments of the present disclosure;

FIG. 3 is a schematic diagram of another structure of a display panel according to some embodiments of the present disclosure;

FIG. 4 is a flow diagram of a manufacturing method of a display panel according to some embodiments of the present disclosure;

FIG. 5 and FIG. 6 are schematic diagrams of structures in a manufacturing process of a display panel according to some embodiments of the present disclosure.

### DETAILED DESCRIPTION

The technical solutions in the embodiments of the present disclosure will be clearly and completely described below with reference to the accompanying drawings in the embodiments of the present disclosure. It is apparent that the embodiments described are only part of the embodiments of the present disclosure, but not all the embodiments of the present disclosure. Based on the embodiments in the present disclosure, all other embodiments obtained by those skilled in the art without making creative efforts fall within the scope of protection of the present disclosure.

Many different implementations or examples are provided in the following disclosure to implement various structures of the present disclosure. In order to simplify the disclosure of the present disclosure, the components and arrangements of specific examples are described below. It is apparent that they are merely examples and are not intended to limit the present disclosure. In addition, reference numbers and/or reference letters can be repeated in different examples of the present disclosure, such repetition is for purposes of simplicity and clarity and does not in itself indicate a relationship between various embodiments and/or arrangements discussed. In addition, examples of various specific processes and materials are provided in the present disclosure, but those of ordinary skill in the art will recognize the application of other processes and/or the use of other materials.

An embodiment of the present disclosure provides a display panel including: a substrate; a pixel defining layer disposed on the substrate, wherein the pixel defining layer includes a first spacer layer and a conductive layer that are stacked, the first spacer layer is located between the conductive layer and the substrate, and a plurality of pixel openings penetrating the first spacer layer and the conductive layer are disposed in the pixel defining layer; a light-emitting layer including a plurality of light-emitting portions disposed in the plurality of pixel openings; a first cathode layer including a plurality of cathode portions disposed in the plurality of pixel openings, each of the plurality of cathode portions is located on a side of each of the plurality of light-emitting portions away from the substrate, and the plurality of cathode portions are electrically connected to the conductive layer; and a second cathode layer disposed on a side of the pixel defining layer away from the substrate; wherein the second cathode layer is electrically connected to the conductive layer.

In one embodiment of the present disclosure, the pixel defining layer further includes a second spacer layer disposed on a side of the conductive layer away from the first spacer layer, and each of the plurality of pixel openings passes through the first spacer layer, the conductive layer and the second spacer layer.

In one embodiment of the present disclosure, wherein a plurality of first openings are disposed in the second spacer layer, each of the plurality of first openings is spaced apart from each of the plurality of pixel openings, and the second cathode layer covers a side of the second spacer layer away from the conductive layer and is connected to the conductive layer through each of the plurality of first openings.

In one embodiment of the present disclosure, each of the plurality of pixel openings includes a second opening penetrating the first spacer layer and an undercut opening penetrating the conductive layer and the second spacer layer, and in the undercut opening, each of side surfaces of the conductive layer is retracted toward a side away from a center of the undercut opening relative to each of side surfaces of the second spacer layer; and each of the plurality of cathode portions extends into the undercut opening and is connected to side surfaces of the conductive layer located in the undercut opening.

In one embodiment of the present disclosure, the second cathode layer extends into the undercut opening and is connected to the side surfaces of the conductive layer located in the undercut opening.

In one embodiment of the present disclosure, the second cathode layer covers a surface on a side of the conductive layer away from the first spacer layer, and covers the plurality of pixel openings.

In one embodiment of the present disclosure, in each of the plurality of pixel openings, each of the plurality of cathode portions and the second cathode layer are connected to side surfaces of the conductive layer located in each of the plurality of pixel openings.

In one embodiment of the present disclosure, the display panel further includes a plurality of protective portions disposed in the plurality of pixel openings, and in each of the plurality of pixel openings, each of the plurality of protective portions is located between each of the plurality of cathode portions and the second cathode layer.

In one embodiment of the present disclosure, a distance from a surface on a side of each of the plurality of protective portions away from the substrate to the substrate is less than a distance from a surface on a side of the conductive layer away from the substrate to the substrate.

In one embodiment of the present disclosure, the conductive layer is disposed around each of the plurality of pixel openings, and the conductive layer is in a grid shape.

In one embodiment of the present disclosure, the display panel further includes an anode layer disposed between the substrate and the pixel defining layer, the anode layer includes a plurality of anodes, each of the plurality of anodes is disposed correspondingly to each of the plurality of pixel openings, each of the plurality of light-emitting portions is disposed between each of the plurality of anodes and each of the plurality of cathode portions, and the first spacer layer is located between the conductive layer and the anode layer.

In one embodiment of the present disclosure, the display panel further includes a display area, a non-display area located on at least one side of the display area, and a cathode signal inputting terminal disposed in the non-display area, and the conductive layer and/or the second cathode layer are connected to the cathode signal inputting terminal.

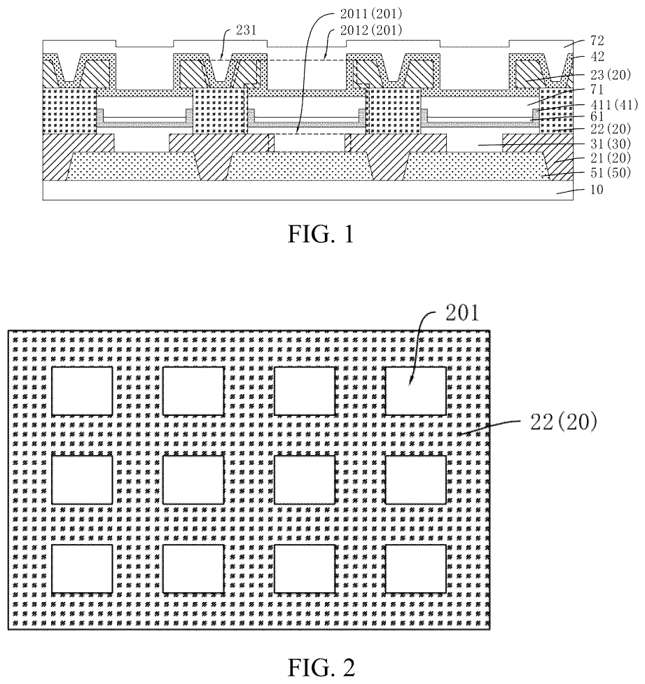

Referring to FIG. 1, an embodiment of the present disclosure provides a display panel, the display panel includes a substrate 10, a pixel defining layer 20, a light-emitting layer 30, a first cathode layer 41 and a second cathode layer 42.

The pixel defining layer 20 is disposed on the substrate 10. The pixel defining layer 20 includes a first spacer layer 21 and a conductive layer 22 that are stacked. The first spacer layer 21 is located between the conductive layer 22 and the substrate 10, and a plurality of pixel openings 201 penetrating the first spacer layer 21 and the conductive layer 22 are disposed in the pixel defining layer 20. The light-emitting layer 30 includes a plurality of light-emitting portions 31 disposed in the plurality of pixel openings 201. The first cathode layer 41 includes a plurality of cathode portions 411 disposed in the plurality of pixel openings 201. Each of the cathode portions 411 is located on the side of each of the light-emitting portions 31 away from the substrate 10, and the plurality of cathode portions 411 are electrically connected to the conductive layer 22. The second cathode layer 42 is disposed on the side of the pixel defining layer 20 away from the substrate 10.

Further, the second cathode layer 42 is electrically connected to the conductive layer 22.

During the implementation and application process, in the embodiments of the present disclosure, by disposing the conductive layer 22 in the pixel defining layer 20, the cathode portion 411 on the light-emitting portion 31 is connected to the second cathode layer 42 on the pixel defining layer 20, so that the second cathode layer 42 is connected in parallel with the conductive layer 22 and the cathode portion 411 which are connected to each other, thereby reducing the resistance of the first cathode layer 41, addressing the voltage drop phenomenon of the display panel, and improving the display uniformity of the display panel.

Specifically, continuing referring to FIG. 1, the display panel provided by the embodiments of the present disclosure includes the substrate 10, an anode layer 50, the pixel defining layer 20, the light emitting layer 30, the first cathode layer 41, the second cathode layer 42 and an encapsulation layer 72.

The anode layer 50 includes a plurality of anodes 51 disposed on the substrate 10, and the plurality of anodes 51 are spaced apart.

The pixel defining layer 20 is disposed on the substrate 10 and covers the plurality of anodes 51. A plurality of pixel openings 201 are provided in the pixel defining layer 20. Each of the plurality of pixel openings 201 is disposed correspondingly to each of the plurality of anodes 51, and each of the anodes 51 is correspondingly exposed by each of the pixel openings 201. It can be understood that the upper surface of the anode 51 is the surface on the side of the anode 51 away from the substrate 10.

The light-emitting layer 30 includes a plurality of light-emitting portions 31. The plurality of light-emitting portions 31 are disposed in the plurality of pixel openings 201 and located on the side of the anodes 51 away from the substrate 10. In one embodiment, each of the light-emitting portions 31 is correspondingly located in one of the pixel openings 201 and is located on the side of a corresponding anode 51 away from the substrate 10.

The first cathode layer 41 includes a plurality of cathode portions 411, the plurality of cathode portions 411 are disposed in the plurality of pixel openings 201 and located on the side of the light-emitting portions 31 away from the anodes 51. In one embodiment, each of the cathode portions 411 is correspondingly located in each of the pixel openings 201 and is located on the side of a corresponding light-emitting portion 31 away from the corresponding anode 51, so that each light-emitting portion 31 is located between the corresponding anode 51 and the corresponding cathode portion 411.

It should be noted that the display panel further includes a thin film transistor layer (not shown in the figure) disposed between the substrate 10 and the pixel defining layer 20. The thin film transistor layer includes a plurality of thin film transistors and signal lines disposed on the substrate 10, and some thin film transistors can be connected to the plurality of anodes 51 to input signals to the plurality of anodes 51.

In some embodiments of the present disclosure, the pixel defining layer 20 includes a first spacer layer 21 and a conductive layer 22 that are stacked. The first spacer layer 21 is located between the substrate 10 and the conductive layer 22, the pixel opening 201 penetrates the first spacer layer 21 and the conductive layer 22, the first spacer layer 21 is located between the conductive layer 22 and the anode layer 50 to separate the conductive layer 22 and the anode 51, so as to avoid short circuiting between the conductive layer 22 and the anode 51. The material of the first spacer layer 21 includes an insulating material, for example, at least one of silicon nitride and silicon oxide, and the material of the conductive layer 22 includes a conductive material, such as metal aluminum.

The plurality of cathode portions 411 are connected to the conductive layer 22. Specifically, since the pixel opening 201 penetrates the conductive layer 22, the side surfaces of the conductive layer 22 are exposed in the pixel opening 201, and the cathode portions 411 are connected to the side surfaces of the conductive layer 22 in the pixel openings 201.

In one embodiment, referring to FIG. 1 and FIG. 2, the conductive layer 22 is disposed around the pixel openings 201, and the conductive layer 22 is arranged in a grid shape in a top viewing angle, so that in the pixel openings 201, the plurality of cathode portions 411 are connected to the side surfaces of the conductive layer 22 located in the pixel openings 201, and the plurality of cathode portions 411 can be connected through the conductive layer 22 to form a cathode electrode structure on the entire surface.

In some embodiments of the present disclosure, the second cathode layer 42 covers the side of the pixel defining layer 20 away from the substrate 10, and the second cathode layer 42 is electrically connected to the conductive layer 22, so that the second cathode layer 42 is connected in parallel with the plurality of cathode portions 411 and the conductive layer 22, so as to reduce the resistance of the cathode electrode structure formed by the plurality of cathode portions 411 and the conductive layer 22, thereby addressing the voltage drop phenomenon of the display panel.

The display panel further includes a display area, a non-display area located on at least one side of the display area, and a cathode signal inputting terminal disposed in the non-display area. The conductive layer 22 and/or the second cathode layer 42 are connected to the cathode signal inputting terminal, that is, in the embodiments of the present disclosure, the cathode signal can be input through at least one of the conductive layer 22 and the second cathode layer 42.

In one embodiment, the materials of the second cathode layer 42 and the first cathode layer 41 include transparent conductive materials.

In one embodiment, the display panel further includes a plurality of protective portions 71, each of the protective portions 71 is disposed in the pixel opening 201 and between the cathode portion 411 and the second cathode layer 42, and the protective portion 71 covers the side of the cathode portion 411 away from the light-emitting portion 31. The material of the protective portion 71 includes at least one of silicon nitride and silicon oxide to provide protection for the cathode portion 411, which can avoid the oxidation reaction of the cathode portion 411 during the manufacturing process or during use, thereby improving the yield rate of the display panel.

Further, in one embodiment, the display panel further includes a plurality of light extraction portions 61, each of the light extraction portions 61 is disposed in the pixel opening 201 and located on the side of the cathode portion 411 away from the light-emitting portion 31. The light extraction portion 61 is located between the cathode portion 411 and the protective portion 71, and the light extraction portion 61 covers the light-extracting side of the light-emitting portion 31, so as to improve the light extracting efficiency of the light-emitting portions 31.

The encapsulation layer 72 covers the side of the second cathode layer 42 away from the pixel defining layer 20, and the material of the encapsulation layer 72 includes at least one of silicon oxide and silicon nitride.

In one embodiment of the present disclosure, referring to FIG. 1, the pixel defining layer 20 further includes a second spacer layer 23 disposed on the side of the conductive layer 22 away from the first spacer layer 21, and each of the pixel openings 201 penetrates the first spacer layer 21, the conductive layer 22 and the second spacer layer 23.

The second spacer layer 23 is provided with a plurality of first openings 231 spaced apart from the pixel openings 201, and the first openings 231 are located on the side of the conductive layer 22 away from the first spacer layer 21. The second cathode layer 42 covers the side of the second spacer layer 23 away from the conductive layer 22 and is connected to the conductive layer 22 through the first openings 231.

Further, each of the pixel openings 201 includes a second opening 2011 penetrating the first spacer layer 21 and an undercut opening 2012 penetrating the conductive layer 22 and the second spacer layer 23. In the undercut opening 2012, the side surfaces of the conductive layer 22 are retracted toward the sides away from the center of the undercut opening 2012 relative to the side surfaces of the second spacer layer 23, so that the side surfaces of the second spacer layer 23 protrude into the undercut opening 2012.

In one embodiment, the aperture of the second opening 2011 is smaller than the aperture of the undercut opening 2012. The light-emitting portion 31 is filled in the second opening 2011 and is partially located at the bottom portion of the undercut opening 2012. The cathode portion 411 is located on the side of the light-emitting portion 31 away from the anode 51, and is located in the undercut opening 2012 and connected to the side surfaces of the conductive layer 22 located in the undercut opening 2012.

Further, the second cathode layer 42 further extends into the undercut opening 2012 and covers the side of the protective portion 71 away from the cathode portion 411. The second cathode layer 42 is connected to the side surfaces of the conductive layer 22 located in the undercut opening 2012. In some embodiments, in addition to being connected to the conductive layer 22 through the first opening 231, the second cathode layer 42 can also be connected to the conductive layer 22 through the undercut opening 2012, so as to increase the contacting area of the second cathode layer 42 and the conductive layer 22 and reduce the connecting resistance, thereby further addressing the voltage drop phenomenon of the display panel, and improving the display uniformity of the display panel.

In one embodiment, the distance from the surface of the protective portion 71 away from the substrate 10 to the substrate 10 is less than the distance from the surface of the conductive layer 22 away from the substrate 10 to the substrate 10, so as to prevent the protective portion 71 from completely covering the side surfaces of the conductive layer 22 located in the undercut opening 2012, so that the portion of the second cathode layer 42 extending into the undercut opening 2012 can be connected to the side surfaces of the conductive layer 22.

The encapsulation layer 72 covers the side of the second cathode layer 42 away from the pixel defining layer 20 and fills the first opening 231 and the undercut opening 2012.

Following the above, in the embodiments of the present disclosure, by disposing the conductive layer 22 in the pixel defining layer 20, the cathode portion 411 on the light-emitting portion 31 is connected to the second cathode layer 42 on the pixel defining layer 20, so that the second cathode layer 42 is connected in parallel with the conductive layer 22 and the cathode portion 411 which are connected to each other, thereby reducing the resistance of the first cathode layer 41, addressing the voltage drop phenomenon of the display panel, and improving the display uniformity of the display panel.

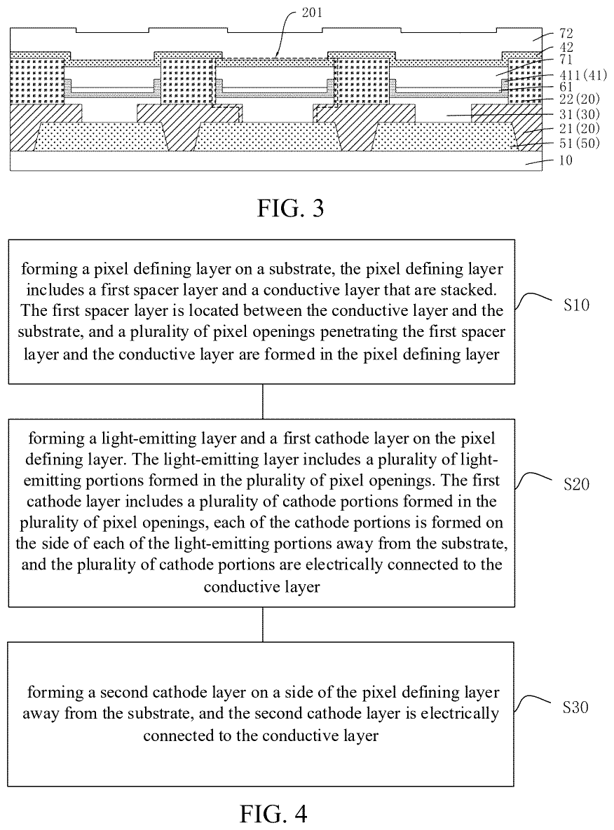

In another embodiment of the present disclosure, referring to FIG. 3, the difference between this embodiment and the embodiment shown in FIG. 1 is that: the pixel definition layer 20 includes a first spacer layer 21 and a conductive layer 22 that are stacked, but does not include a second spacer layer.

The second cathode layer 42 covers the surface of the side of the conductive layer 22 away from the first spacer layer 21 and covers the plurality of pixel openings 201. The portion of the second cathode layer 42 located in the pixel opening 201 is connected to the side surfaces of the conductive layer 22 located in the pixel opening 201 and covers the side of the protective portion 71 away from the cathode portion 411. In the pixel opening 201, the cathode portion 411 is connected to the side surfaces of the conductive layer 22 located in the pixel opening 201.

Following the above, in the embodiments of the present disclosure, by disposing the conductive layer 22 in the pixel defining layer 20, the cathode portion 411 on the light-emitting portion 31 is connected to the second cathode layer 42 on the pixel defining layer 20, so that the second cathode layer 42 is connected in parallel with the conductive layer 22 and the cathode portion 411 which are connected to each other, thereby reducing the resistance of the first cathode layer 41, addressing the voltage drop phenomenon of the display panel, and improving the display uniformity of the display panel. Compared with the embodiment shown in FIG. 1, in the present embodiment, the arrangement of the second spacer layers 23 is reduced, the contacting area between the second cathode layer 42 and the conductive layer 22 is further increased, thereby reducing the resistance.

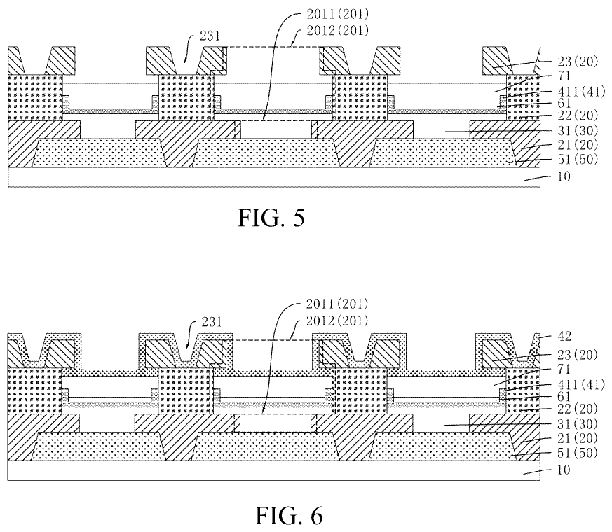

In addition, an embodiment of the present disclosure further provides a manufacturing method of the display panel described in the above embodiments. Referring to FIG. 1, FIG. 3, FIG. 4, FIG. 5 and FIG. 6, the manufacturing method of the display panel includes the following steps.

S10, forming a pixel defining layer 20 on a substrate 10, the pixel defining layer 20 includes a first spacer layer 21 and a conductive layer 22 that are stacked. The first spacer layer 21 is located between the conductive layer 22 and the substrate 10, and a plurality of pixel openings 201 penetrating the first spacer layer 21 and the conductive layer 22 are formed in the pixel defining layer 20.

S20, forming a light-emitting layer 30 and a first cathode layer 41 on the pixel defining layer 20. The light-emitting layer 30 includes a plurality of light-emitting portions 31 formed in the plurality of pixel openings 201. The first cathode layer 41 includes a plurality of cathode portions 411 formed in the plurality of pixel openings 201, each of the cathode portions 411 is formed on the side of each of the light-emitting portions 31 away from the substrate 10, and the plurality of cathode portions 411 are electrically connected to the conductive layer 22.

S30, forming a second cathode layer 42 on a side of the pixel defining layer 20 away from the substrate 10, and the second cathode layer 42 is electrically connected to the conductive layer 22.

Specifically, in step S10, as shown in FIG. 5, an anode layer 50 is formed on the substrate 10, and the anode layer 50 includes a plurality of anodes 51 spaced apart.

A first spacer material layer, a conductive material layer and a second spacer material layer are sequentially deposited on the substrate 10 and the anode layer 50, the first spacer material layer is located between the conductive material layer and the substrate 10, and the conductive material layer is located between the first spacer material layer and the second spacer material layer.

Then, the first spacer material layer, the conductive material layer and the second spacer material layer which are stacked are patterned through a photolithography process, so as to form the first spacer layer 21, the conductive layer 22 and the second spacer layer 23 that are stacked. The first spacer layer 21 is located between the conductive layer 22 and the substrate 10, the conductive layer 22 is located between the first spacer layer 21 and the second spacer layer 23, and the first spacer layer 21, the conductive layer 22 and the second spacer layer 23 which are stacked constitute the pixel defining layer 20.

During the patterning process, a plurality of pixel openings 201 penetrating the first spacer layer 21, the conductive layer 22 and the second spacer layer 23 are formed in the pixel defining layer 20, and the plurality of pixel openings 201 are disposed correspondingly to the plurality of anodes 51, so as to expose the surface on the side of the corresponding anode 51 away from the substrate 10.

In step S20, a light-emitting material layer, a first cathode material layer, and a light extraction material layer are formed on the entire surface of the pixel defining layer 20 by using an evaporation process, and then a protective material layer is formed on the entire surface by using a chemical vapor deposition method.

The light-emitting material layer, the first cathode material layer, the light extraction material layer and the protective material layer are patterned through a photolithography process to form the light-emitting layer 30, the first cathode layer 41, the light extraction portions 61 and the protective portions 71. The light-emitting layer 30 includes a plurality of light-emitting portions 31 disposed in the plurality of pixel openings 201, and the first cathode layer 41 includes a plurality of cathode portions 411 disposed in the plurality of pixel openings 201. In the pixel opening 201, the light-emitting portion 31 is located on the side of the anode 51 away from the substrate 10, the cathode portion 411 is located on the side of the light-emitting portion 31 away from the anode 51, the light extraction portion 61 is located on the side of the cathode portion 411 away from the light-emitting portion 31, and the protective portion 71 is located on the side of the light extraction portion 61 away from the cathode portion 411.

It should be noted that, the pixel opening 201 includes a second opening 2011 penetrating the first spacer layer 21 and an undercut opening 2012 penetrating the conductive layer 22 and the second spacer layer 23. In the undercut opening 2012, the side surfaces of the conductive layer 22 are retracted toward the sides away from the center of the undercut opening 2012 relative to the side surfaces of the second spacer layer 23, so that the side surfaces of the second spacer layer 23 protrude into the undercut opening 2012. This further helps the light-emitting material layer and the first cathode material layer to be broken at the undercut opening 2012, so that the protective portion 71 can cover the cathode portion 411 to avoid the cathode portion 411 from being oxidized during the manufacturing process which will increase the resistance, and thereby improving the yield rate of display panels. In the undercut opening 2012, the cathode portion 411 is connected to the side surfaces of the conductive layer 22 located in the undercut opening 2012.

In one embodiment, the plurality of light-emitting portions 31 may include at least one light-emitting portion 31 emitting red light, at least one light-emitting portion 31 emitting green light, and at least one light-emitting portion 31 emitting blue light.

During the manufacturing process, the light-emitting material layer corresponding to the light-emitting portion 31 corresponding to the red light, the first cathode material layer, the light extraction material layer and the protective material layer may be manufactured first to form the light-emitting portion 31 emitting red light, the corresponding cathode portion 411, light extraction portion 61 and protective portion 71 in the corresponding pixel opening 201.

The light-emitting portions 31 emitting green light and blue light and the corresponding cathode portions 411, light extraction portions 61 and protective portions 71 can be then completed according to the above process.

It can be understood that the display panel in the embodiments of the present disclosure can be manufactured using the environment positive lithography with maskless deposition (eLEAP) technology. In the embodiments of the present disclosure, when the pixel defining layer 20, the light-emitting layer 30, the first cathode layer 41, the light extraction portion 61 and the protective portion 71 are formed by patterning, the photolithography process is used for preparation, and the light-emitting layer 30 is not obtained by evaporation through a mask. That is, the embodiments of the present disclosure can reduce the use of the mask and avoid the limitations of the pattern, process and accuracy of the mask during the patterning process, thereby improving the applicability of the display panel.

In step S30, a plurality of first openings 231 penetrating the second spacer layer 23 are formed in the second spacer layer 23, and each of the first openings 231 is spaced apart from each of the pixel openings 201.

The second cathode layer 42 is formed on the side of the pixel defining layer 20 away from the substrate 10. The second cathode layer 42 covers the side of the pixel defining layer 20 away from the substrate 10 and is connected to the conductive layer 22 through the first opening 231. Further, the second cathode layer 42 further extends into the undercut opening 2012 of the pixel opening 201 and is connected to the side surface of the conductive layer 22 located in the undercut opening 2012.

It should be noted that the first opening 231 and the pixel opening 201 may be formed in the same process, or may be formed in different processes.

In another embodiment of the present disclosure, as shown in FIG. 3, in step S20, the second spacer layer 23 can be directly removed, and then the second cathode layer 42 is formed on the side of the conductive layer 22 away from the first spacer layer 21. The second cathode layer 42 covers the surface on the side of the conductive layer 22 away from the first spacer layer 21, and extends into the pixel opening 201 and is connected to the side surfaces of the conductive layer 22 located in the pixel opening 201.

Next, the encapsulation layer 72 is formed on the side of the second cathode layer 42 away from the pixel defining layer 20.

In summary, in the embodiments of the present disclosure, by disposing the conductive layer 22 in the pixel defining layer 20, the cathode portion 411 on the light-emitting portion 31 is connected to the second cathode layer 42 on the pixel defining layer 20, so that the second cathode layer 42 is connected in parallel with the conductive layer 22 and the cathode portion 411 which are connected to each other, thereby reducing the resistance of the first cathode layer 41, addressing the voltage drop phenomenon of the display panel, and improving the display uniformity of the display panel.

An embodiment of the present disclosure further provides a display device; the display device includes the display panel in any of the embodiments described above.

In one embodiment, the display device may include a mobile phone, a television, a computer, a tablet, and other display or lighting devices.

It can be understood that since the display device is provided with the same display panel in the embodiments described above, the display device has the same beneficial effects as the display panel described above, which will not be described again herein.

In the above embodiments, each embodiment is described with its own emphasis. For parts that are not described in detail in a certain embodiment, reference can be made to the relevant descriptions of other embodiments.

The display panel, the manufacturing method of the display panel and the display device provided by the embodiments of the present disclosure have been introduced in detail above. Specific examples are used herein to illustrate the principles and implementations of the present disclosure, and the above description of the embodiments is merely intended to help understand the technical solution and its core idea of the present disclosure. It should be understood that, a person skilled in the art may modify the technical solutions recorded in the foregoing embodiments, or to equivalently replace some of the technical features. However, these modifications or replacements do not cause the essence of the corresponding technical solution to depart from the scope of the technical solution of each embodiment of the present disclosure.

What is claimed is:

1. A display panel comprising:
a substrate;
a pixel defining layer disposed on the substrate, wherein the pixel defining layer comprises a first spacer layer and a conductive layer that are stacked, the first spacer layer is located between the conductive layer and the substrate, and a plurality of pixel openings penetrating the first spacer layer and the conductive layer are disposed in the pixel defining layer;
a light-emitting layer comprising a plurality of light-emitting portions disposed in the plurality of pixel openings;
a first cathode layer comprising a plurality of cathode portions disposed in the plurality of pixel openings, each of the plurality of cathode portions is located on a side of each of the plurality of light-emitting portions away from the substrate, and the plurality of cathode portions are electrically connected to the conductive layer; and
a second cathode layer disposed on a side of the pixel defining layer away from the substrate;
wherein the second cathode layer is electrically connected to the conductive layer.

2. The display panel according to claim 1, wherein the pixel defining layer further comprises a second spacer layer disposed on a side of the conductive layer away from the first spacer layer, and each of the plurality of pixel openings passes through the first spacer layer, the conductive layer and the second spacer layer.

3. The display panel according to claim 2, wherein a plurality of first openings are disposed in the second spacer layer, each of the plurality of first openings is spaced apart from each of the plurality of pixel openings, and the second cathode layer covers a side of the second spacer layer away from the conductive layer and is connected to the conductive layer through each of the plurality of first openings.

4. The display panel according to claim 2, wherein each of the plurality of pixel openings comprises a second opening penetrating the first spacer layer and an undercut opening penetrating the conductive layer and the second spacer layer, and in the undercut opening, each of side surfaces of the conductive layer is retracted toward a side away from a center of the undercut opening relative to each of side surfaces of the second spacer layer; and
wherein each of the plurality of cathode portions extends into the undercut opening and is connected to the side surfaces of the conductive layer located in the undercut opening.

5. The display panel according to claim 4, wherein the second cathode layer extends into the undercut opening and is connected to the side surfaces of the conductive layer located in the undercut opening.

6. The display panel according to claim 1, wherein the second cathode layer covers a surface on a side of the conductive layer away from the first spacer layer, and covers the plurality of pixel openings.

7. The display panel according to claim 6, wherein in each of the plurality of pixel openings, each of the plurality of cathode portions and the second cathode layer are connected to side surfaces of the conductive layer located in each of the plurality of pixel openings.

8. The display panel according to claim 1, wherein the display panel further comprises a plurality of protective portions disposed in the plurality of pixel openings, and in each of the plurality of pixel openings, each of the plurality of protective portions is located between each of the plurality of cathode portions and the second cathode layer.

9. The display panel according to claim 8, wherein a distance from a surface on a side of each of the plurality of protective portions away from the substrate to the substrate is less than a distance from a surface on a side of the conductive layer away from the substrate to the substrate.

10. The display panel according to claim 1, wherein the conductive layer is disposed around each of the plurality of pixel openings, and the conductive layer is in a grid shape.

11. The display panel according to claim 1, wherein the display panel further comprises an anode layer disposed between the substrate and the pixel defining layer, the anode layer comprises a plurality of anodes, each of the plurality of anodes is disposed correspondingly to each of the plurality of pixel openings, each of the plurality of light-emitting portions is disposed between each of the plurality of anodes and each of the plurality of cathode portions, and the first spacer layer is located between the conductive layer and the anode layer.

12. The display panel according to claim 1, wherein the display panel further comprises a display area, a non-display area located on at least one side of the display area, and a cathode signal inputting terminal disposed in the non-display area, and the conductive layer and/or the second cathode layer are connected to the cathode signal inputting terminal.

13. A manufacturing method of a display panel comprising:
forming a pixel defining layer on a substrate, wherein the pixel defining layer comprises a first spacer layer and a conductive layer that are stacked, the first spacer layer is located between the conductive layer and the substrate, and a plurality of pixel openings penetrating the first spacer layer and the conductive layer are disposed in the pixel defining layer;
forming a light-emitting layer and a first cathode layer on the pixel defining layer, wherein the light-emitting layer comprises a plurality of light-emitting portions formed in the plurality of pixel openings, the first cathode layer comprises a plurality of cathode portions formed in the plurality of pixel openings, each of the plurality of cathode portions is formed on a side of each of the plurality of light-emitting portions away from the substrate, and the plurality of cathode portions are electrically connected to the conductive layer; and
forming a second cathode layer on a side of the pixel defining layer away from the substrate, wherein the second cathode layer is electrically connected to the conductive layer.

14. A display device, wherein the display device comprises a display panel, wherein the display panel comprises:
a substrate;
a pixel defining layer disposed on the substrate, wherein the pixel defining layer comprises a first spacer layer and a conductive layer that are stacked, the first spacer layer is located between the conductive layer and the substrate, and a plurality of pixel openings penetrating the first spacer layer and the conductive layer are disposed in the pixel defining layer;
a light-emitting layer comprising a plurality of light-emitting portions disposed in the plurality of pixel openings;
a first cathode layer comprising a plurality of cathode portions disposed in the plurality of pixel openings, each of the plurality of cathode portions is located on a side of each of the plurality of light-emitting portions away from the substrate, and the plurality of cathode portions are electrically connected to the conductive layer; and
a second cathode layer disposed on a side of the pixel defining layer away from the substrate;
wherein the second cathode layer is electrically connected to the conductive layer.

15. The display device according to claim 14, wherein the pixel defining layer further comprises a second spacer layer disposed on a side of the conductive layer away from the first spacer layer, and each of the plurality of pixel openings passes through the first spacer layer, the conductive layer and the second spacer layer.

16. The display device according to claim 15, wherein a plurality of first openings are disposed in the second spacer layer, each of the plurality of first openings is spaced apart from each of the plurality of pixel openings, and the second cathode layer covers a side of the second spacer layer away from the conductive layer and is connected to the conductive layer through each of the plurality of first openings.

17. The display device according to claim 15, wherein each of the plurality of pixel openings comprises a second opening penetrating the first spacer layer and an undercut opening penetrating the conductive layer and the second spacer layer, and in the undercut opening, each of side surfaces of the conductive layer is retracted toward a side away from a center of the undercut opening relative to each of side surfaces of the second spacer layer; and
wherein each of the plurality of cathode portions extends into the undercut opening and is connected to the side surfaces of the conductive layer located in the undercut opening.

18. The display device according to claim 17, wherein the second cathode layer extends into the undercut opening and is connected to the side surfaces of the conductive layer located in the undercut opening.

19. The display device according to claim 14, wherein the second cathode layer covers a surface on a side of the conductive layer away from the first spacer layer, and covers the plurality of pixel openings.

20. The display device according to claim 19, wherein in each of the plurality of pixel openings, each of the plurality of cathode portions and the second cathode layer are connected to side surfaces of the conductive layer located in each of the plurality of pixel openings.
